(19) United States
(12) Patent Application Publication
(10) Pub. No.: US 2009/0300911 A1
(43) Pub. Date: Dec. 10, 2009

(54) METHOD OF MANUFACTURING WIRING SUBSTRATE AND CHIP TRAY

(75) Inventors: Mitsutoshi Higashi, Nagano-shi (JP); Kei Murayama, Nagano-shi (JP); Masahiro Sunohara, Nagano-shi (JP); Hideaki Sakaguchi, Nagano-shi (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd., Nagano-shi (JP)

(21) Appl. No.: 12/478,215

(22) Filed: Jun. 4, 2009

(30) Foreign Application Priority Data
Jun. 5, 2008 (JP) 2008-148222

(51) Int. Cl. H05K 3/32; H05K 13/00

(52) U.S. Cl. 29/831; 29/832; 29/740; 257/E21.575

(57) ABSTRACT

A method of manufacturing a wiring substrate comprises the steps of attaching a semiconductor chip to a chip positioning plate of a chip tray formed of silicon, executing wiring formation processing using the semiconductor chip attached to the chip positioning plate as a base point, and detaching the wiring-formed wiring substrate from the chip positioning plate. The chip positioning plate comprises a receiving part for receiving the semiconductor chip, and elastic members respectively disposed in two adjacent surfaces of four surfaces constructing an inside surface of the receiving part, and each of these elastic members exerts pressing force toward directions of opposite surfaces, and the semiconductor chip is pinched between each of the opposite surfaces corresponding to each of the elastic members.

This application claims priority to Japanese Patent Application No. 2008-148222, filed Jun. 5, 2008, in the Japanese Patent Office. The Japanese Patent Application No. 2008-148222 is incorporated by reference in its entirety.

### TECHNICAL FIELD

The present disclosure relates to a method of manufacturing a wiring substrate in which a semiconductor chip is mounted, and a chip tray for demarcating a position of a semiconductor chip to be mounted at the time of manufacturing a wiring substrate.

### RELATED ART

In a manufacturing process of a wiring substrate such as a build-up substrate in which a semiconductor chip (IC chip) is mounted, wiring is generally formed using the semiconductor chip to be mounted as a base point. In this case, various processing such as wiring formation processing or individualizing processing is executed after the semiconductor chip is fixed using a fixing jig.

There is, for example, a method of manufacturing a wiring substrate in which a semiconductor chip is mounted by using an adhesive tape as a fixing jig. More specifically, the semiconductor chip to be mounted is pasted on the adhesive tape and then, while moving the tape, on which the semiconductor chip is pasted, along a manufacturing line using a carrying apparatus, wiring formation processing using the semiconductor chip as a base point is executed (for example, see Patent Reference 1).

FIGS. 5A to 5C are views describing a manufacturing process of a wiring substrate in which a semiconductor chip is mounted according to a related art. First, as shown in FIG. 5A, semiconductor chips 100 are positioned and stuck on a support body 200 such as glass in which an adhesive layer 150 is pasted on one surface. Next, as shown in FIG. 5B, an insulating resin 250 is provided and vias are formed by a laser etc. and various wiring 300 is formed using a photolithography technique. A resist film 350 is patterned on the uppermost layer. Therefore, a wiring substrate structure body including the semiconductor chips 100, the insulating resin 250, the wiring 300 and the resist film 350 is formed on the support body 200 through the adhesive layer 150. Then, as shown in FIG. 5C, the support body 200 and the adhesive layer 150 are peeled from the wiring substrate structure body and the wiring substrate structure body is individualized into wiring substrates 400 (FIG. 5C shows only one wiring substrate 400).

Also, there is a method of manufacturing a wiring substrate in which a semiconductor chip is mounted by using a chip tray having a cavity as a fixing jig. More specifically, the semiconductor chip is attached to the cavity of the chip tray and while moving the chip tray, to the cavity of which the semiconductor chip is attached, along a manufacturing line, wiring formation processing using the semiconductor chip as a base point is executed (for example, see Patent Reference 2).

[Patent Reference 1] JP-A-10-203064

[Patent Reference 2] JP-A-2006-128585

In the related-art manufacturing process of the wiring substrate, in a stage of wiring formation processing, a stage of individualizing processing or a stage of removing a wiring substrate in which a semiconductor chip is already mounted from a fixing jig after wiring is formed, a defect in a wiring substrate product resulting from the fixing jig tends to occur. Particularly, in the case of collectively processing multiple semiconductor chips, an error tends to occur in positioning of the semiconductor chips and accuracy is reduced.

Particularly, in the method using a chip tray in which a semiconductor chip is attached to a cavity, in order to enable attachment and detachment of the semiconductor chip to/from the chip tray, the cavity must be formed somewhat larger than a size of the semiconductor chip with an allowance and this allowance became one cause of reducing position accuracy. Also, the chip tray differs from a main component member of the wiring substrate or the semiconductor chip in material and thus in an expansion coefficient. This respect also became one cause of reducing position accuracy.

### SUMMARY

Exemplary embodiments of the present invention provide a method of manufacturing a wiring substrate capable of implementing positioning of a semiconductor chip to be mounted in a manufacturing process easily with high accuracy, and a chip tray for demarcating a position of a semiconductor chip to be mounted at the time of manufacturing a wiring substrate easily with high accuracy.

In the invention, a method of manufacturing a wiring substrate in which a semiconductor chip is mounted, comprises steps of:

attaching a semiconductor chip to be mounted in a wiring substrate to a chip positioning plate of a chip tray, the whole chip tray being formed of silicon;

executing a wiring formation processing using the semiconductor chip attached to the chip positioning plate as a base point to form a wiring substrate in which a wiring is formed on the semiconductor chip; and

detaching the wiring substrate from the chip positioning plate.

The chip positioning plate comprises a receiving part which has an inside surface constructed by four surfaces and receives the semiconductor chip, and elastic members which are respectively disposed along two adjacent surfaces of the four surfaces constructing the inside surface of the receiving part, each of the elastic members having pressing force toward a direction of the surface opposite to the surface constructing the inside surface of the receiving part along which the elastic member is disposed, and in the attaching step, the semiconductor chip is pinched between each of the elastic members and each of the opposite surfaces of the receiving part, corresponding to each of the elastic members.

Also, according to the invention, a chip tray comprises a chip positioning plate formed of silicon, having a receiving part which has an inside surface constructed by four surfaces and receives a semiconductor chip to be mounted in a wiring substrate, and elastic members which are respectively disposed along two adjacent surfaces of the four surfaces constructing the inside surface of the receiving part, each of the elastic members having pressing force toward a direction of the surface opposite to the surface constructing the inside surface of the receiving part along which the elastic member is disposed, so that the semiconductor chip is pinched between each of the elastic members and each of the opposite surfaces of the receiving part, corresponding to each of the elastic members.

According to the invention, amethod of manufacturing a wiring substrate capable of implementing positioning of a semiconductor chip to be mounted in a manufacturing process easily with high accuracy and a chip tray for demarcating a position of a semiconductor chip to be mounted at the time of manufacturing a wiring substrate easily with high accuracy can be implemented.

According to the invention, the whole chip tray used in a method of manufacturing a wiring substrate in which a semiconductor chip is mounted is formed by the same silicon as a main component member of the wiring substrate or the semiconductor chip, so that there is a high affinity between the chip tray and the wiring substrate or the semiconductor chip, and the chip tray and the wiring substrate or the semiconductor chip have the same expansion coefficient. Therefore, positioning of the semiconductor chip can be implemented with high accuracy. Particularly, even in the case of collectively processing multiple semiconductor chips, the positioning can be implemented with high accuracy. Also, since it is easy to handle silicon and the silicon tends to be processed, the chip tray can easily be formed of one silicon plate. Therefore, productivity also improves.

Also, in the invention, a semiconductor chip is fixed using an elastic member, so that a positional deviation is resistant to occurring at the time of wiring formation processing. Also, according to the invention, an adhesive is not used in fixing of the semiconductor chip, so that wastes etc. do not occur. Also, in a chip tray according to the invention, it is easy to attach and detach the semiconductor chip to/from the chip tray, so that reuse of the chip tray is also facilitated and it is economical. Thus, the chip tray and the method of manufacturing a wiring substrate according to the invention have a small load imposed on environment.

Other features and advantages may be apparent from the following detailed description, the accompanying drawings and the claims.

### BRIEF DESCRIPTION OF THE DRAWINGS

FIGS. 1A to 1C are top views of a chip tray according to an embodiment of the invention.

FIGS. 2A to 2B are sectional views of the chip tray according to the embodiment of the invention.

FIG. 3 is a top view describing fixing of a semiconductor chip by a chip positioning plate of the inside of the chip tray according to the embodiment of the invention.

FIGS. 4A to 4D are sectional views of the chip tray and the semiconductor chip describing a method of manufacturing a wiring substrate according to the embodiment of the invention.

FIGS. 5A to 5C are views describing a manufacturing process of a wiring substrate in which a semiconductor chip is mounted according to a related art.

### DETAILED DESCRIPTION

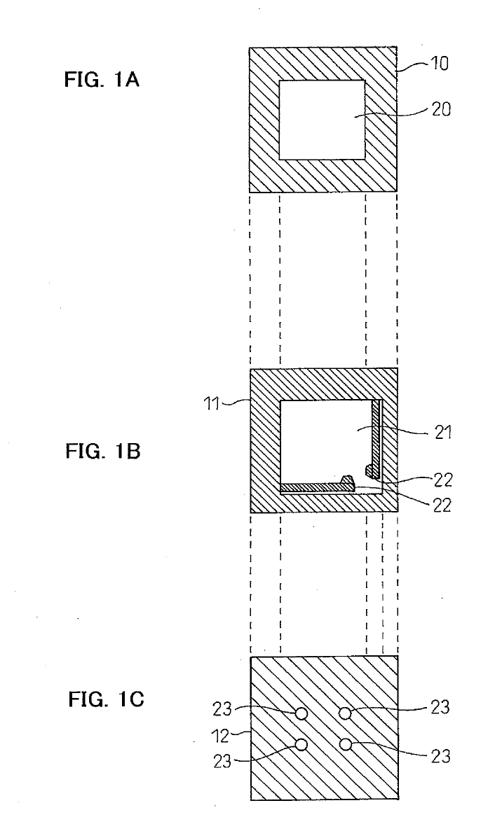

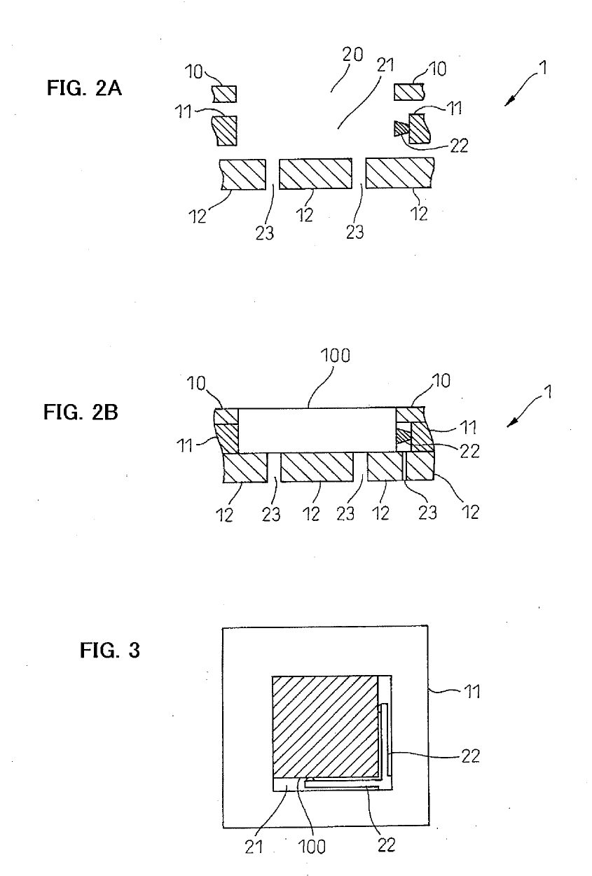

FIGS. 1A to 1C are top views of a chip tray according to an embodiment of the invention, and FIGS. 2A to 2B are sectional views of the chip tray according to the embodiment of the invention. It shall hereinafter mean that components to which the same numerals are assigned in different drawings are the same components.

A chip tray 1 according to the embodiment of the invention comprises a cover plate 10 shown in FIG. 1A and FIGS. 2A and 2B, a chip positioning plate 11 shown in FIG. 1B and FIGS. 2A and 2B, and a base plate 12 shown in FIG. 1C and FIGS. 2A and 2B.

The chip positioning plate 11 is formed of, for example, one silicon plate. The chip positioning plate 11 comprises a plurality of receiving parts 21 (FIG. 1B shows only one receiving part 21) and elastic members 22. Each of the receiving parts 21 is a quadrilateral opening formed in the chip positioning plate 11 and receives a semiconductor chip. The elastic members 22 are respectively disposed along two adjacent surfaces of four surfaces constructing an inside surface of the receiving part 21. Each of the elastic members 22 exerts pressing force toward a direction of the surface opposite to the surface constructing the inside surface the receiving part 21 along which the elastic member 22 is disposed. FIG. 3 is a top view describing fixing of the semiconductor chip by the chip positioning plate 11 of the chip tray according to the embodiment of the invention. FIG. 3 shows elastic members 22 whose structure is different from that of the elastic members 22 of FIG. 1B. In the receiving part 21 of the chip positioning plate 11, a semiconductor chip 100 is pinched between each of the elastic members 22 and each of the opposite surfaces of the receiving part 21 corresponding to each of the elastic members 22, by the pressing force which each of the elastic members 22 exerts toward the direction of the surface opposite to the surface constructing the inside surface of the receiving part 21 along which the elastic member 22 is disposed. Since the plurality of receiving parts 21 are disposed in the chip positioning plate 11 of the chip tray 1, wiring formation processing with respect to the plurality of semiconductor chips can be performed collectively.

The elastic member 22 of the inside of the chip positioning plate 11 is formed by the same silicon as a main component member of the semiconductor chip 100 as described above. Therefore, there is a high affinity between the elastic member 22 and the semiconductor chip 100 and also, the elastic member 22 and the semiconductor chip 100 have the same expansion coefficient, so that positioning of the semiconductor chip can be implemented with high accuracy. Particularly, in the case of collectively processing multiple semiconductor chips, an advantageous effect is achieved. Also, the semiconductor chip 100 is fixed using the elastic members 22, so that a positional deviation is resistant to occurring at the time of wiring formation processing and also it is easy to attach and detach the semiconductor chip 100 to/from the chip tray 1. Also, silicon is an easy-to-process member, so that it is also easy to process a shape and a size of the receiving part 21 of the chip positioning plate 11 with high accuracy.

The cover plate 10 is disposed over the chip positioning plate 11. Since the cover plate 10 is also formed of silicon, it is easy to stick the cover plate 10 on the chip positioning plate 11 formed of silicon similarly. The cover plate 10 has a plurality of opening parts 20 corresponding to the receiving part 21 of the chip positioning plate 11 (FIG. 1A shows only one opening part 20). As shown in FIG. 1A and FIG. 2A, in the cover plate 10, the opening part 20 is disposed so as to expose the semiconductor chip 100 received in the receiving part 21, and the opening part 20 has a size in which the elastic member 22 is covered without exposing the elastic member 22 in the case of viewing the elastic member 22 from above.

The base plate 12 is also formed of silicon. The base plate 12 is disposed under the chip positioning plate 11, and supports the semiconductor chip 100 received in the receiving part 21. Since both of the base plate 12 and the chip positioning plate 11 are formed of silicon, these are also easy to stick.

The base plate 12 has through holes 23 used in degassing of the inside of the receiving part 21 and fixing of the semiconductor chip 100 received in the receiving part 21. For example, the semiconductor chip 100 can be sucked and fixed to the base plate 12 by aspirating air through the through holes 23 and the semiconductor chip 100 can be detached (extruded) from the base plate 12 by pressurizing air through the through holes 23. In addition, detachment of the semiconductor chip 100 from the base plate 12 may be implemented by directly inserting a pin etc. from the through hole 23 and extruding the semiconductor chip. In the chip tray 1 according to the embodiment of the invention thus, it is easy to attach and detach the semiconductor chip 100 to/from the chip tray 1, so that reuse of the chip tray 1 is also facilitated and it is economical. Also, according to the embodiment of the invention, an adhesive is not used in fixing of the semiconductor chip, so that wastes etc. do not occur.

As described above, the chip tray 1 according to the embodiment of the invention is constructed of three layers of the cover plate 10, the chip positioning plate 11 and the base plate 12. The chip tray 1 is fabricated by etching a silicon wafer. Since it is easy to handle silicon and the silicon tends to be processed, productivity also improves.

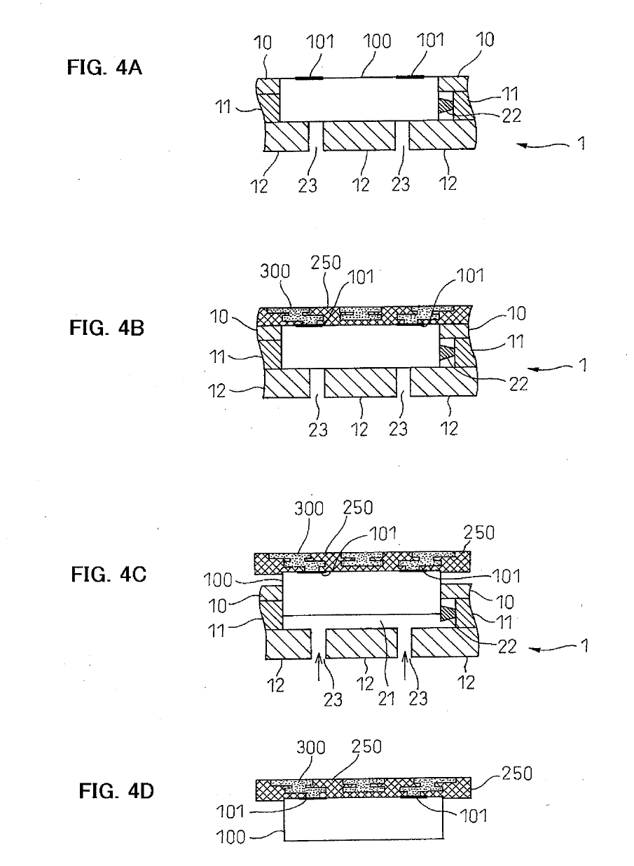

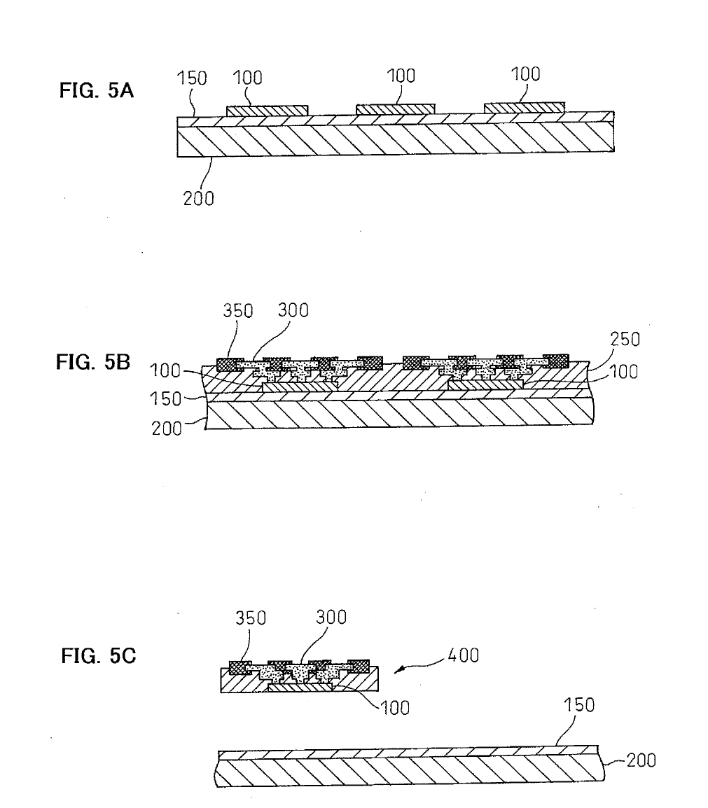

FIGS. 4A to 4D are sectional views of the chip tray and the semiconductor chip describing a method of manufacturing a wiring substrate according to the embodiment of the invention.

First, as shown in FIG. 4A, the semiconductor chip 100 is attached to the chip tray 1 according to the embodiment of the invention described above. At this time, the semiconductor chip 100 is attached to the receiving part 21 of the inside of the chip tray 1 so that a device surface of the semiconductor chip 100 turns upward, that is, terminals 101 of the semiconductor chip 100 turn upward. Also, fixing of the semiconductor chip 100 to the base plate 12 is implemented, for example, using suction by air aspiration through the through holes 23. The through holes 23 also have a function of degassing of the inside of the receiving part 21 in the case of this attachment. The processing described above is performed at a wafer level. More specifically, the plurality of semiconductor chips 100 are attached to the corresponding receiving parts 21 of the inside of the chip tray 1, respectively.

Next, as shown in FIG. 4B, wiring formation processing is executed using the semiconductor chip 100 as a base point. That is, an insulating resin 250 is formed using an organic material or an inorganic film such as an SiO₂ film and vias are formed by a laser etc. and a conductive layer 300 is formed using a photolithography technique. The conductive layer 300 may be Ti, Cr, Cu, Al, Ni, Pb or Au.

Then, as shown in FIG. 4C, by pressurizing air through the through holes 23 from the back side of the chip tray 1, the semiconductor chip 100 is detached (extruded) from the chip positioning plate 11 and the base plate 12 of the chip tray 1. The through holes 23 also have a function of degassing of the inside of the receiving part 21 in the case of this detachment.

Then, as shown in FIG. 4D, the detached wiring-formed wiring substrate structure body including the semiconductor chips 100, the insulating resin 250 and the conductive layer 300 is cut out every each piece of the wiring substrate in which the semiconductor chip 100 is formed.

In the chip tray 1 according to the embodiment of the invention thus, it is easy to attach and detach the semiconductor chip 100 to/from the chip tray 1, so that reuse of the chip tray 1 is also facilitated and it is economical.

It can be applied to fixing and positioning of a semiconductor chip in a manufacturing process of a wiring substrate such as a build-up substrate in which the semiconductor chip (IC chip) is mounted. A chip tray and a method of manufacturing the wiring substrate according to the invention have a very small load imposed on environment.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A method of manufacturing a wiring substrate in which a semiconductor chip is mounted, comprising steps of:
attaching a semiconductor chip to be mounted in a wiring substrate to a chip positioning plate of a chip tray, the whole chip tray being formed of silicon;
executing a wiring formation processing using the semiconductor chip attached to the chip positioning plate as a base point to form a wiring substrate in which a wiring is formed on the semiconductor chip; and
detaching the wiring substrate from the chip positioning plate.

2. A method of manufacturing a wiring substrate as claimed in claim 1, wherein the chip positioning plate comprises a receiving part which has an inside surface constructed by four surfaces and receives the semiconductor chip, and elastic members which are respectively disposed along two adjacent surfaces of the four surfaces constructing the inside surface of the receiving part, each of the elastic members having pressing force toward a direction of the surface opposite to the surface constructing the inside surface of the receiving part along which said elastic member is disposed, and
wherein in the attaching step, the semiconductor chip is pinched between each of the elastic members and each of the opposite surfaces of the receiving part, corresponding to each of the elastic members.

3. A method of manufacturing a wiring substrate as claimed in claim 2, wherein the chip tray further comprises a cover plate which is disposed over the chip positioning plate so as to cover the elastic members and expose the semiconductor chip received in the receiving part, and a base plate which supports the semiconductor chip received in the receiving part and is disposed under the chip positioning plate, the base plate having a through hole used in degassing of the inside of the receiving part and fixing of the semiconductor chip received in the receiving part.

4. A method of manufacturing a wiring substrate as claimed in claim 3, wherein in the attaching step, the semiconductor chip is sucked and fixed to the base plate by aspirating air through the through hole and, in the detaching step, the semiconductor chip is detached from the base plate by pressurizing air through the through hole.

5. A method of manufacturing a wiring substrate as claimed in claim 1, wherein the plural receiving parts are disposed in the chip positioning plate of the chip tray, and
wherein in the attaching step, a plurality of semiconductor chips are received in the corresponding receiving parts.

6. A method of manufacturing a wiring substrate as claimed in claim 5, further comprising a step of:
cutting out the wiring substrate including the semiconductor chips and the wiring formed on the semiconductor chips detached from the chip positioning plate every each piece.

7. A chip tray, comprising:
a chip positioning plate formed of silicon, having a receiving part which has an inside surface constructed by four surfaces and receives a semiconductor chip to be mounted in a wiring substrate, and elastic members which are respectively disposed along two adjacent surfaces of the four surfaces constructing the inside surface of the receiving part, each of the elastic members having pressing force toward a direction of the surface opposite to the surface constructing the inside surface of the receiving part along which said elastic member is disposed, so that the semiconductor chip is pinched between each of the elastic members and each of the opposite surfaces of the receiving part, corresponding to each of the elastic members.

8. A chip tray as claimed in claim 7, further comprising:
a cover plate formed of silicon, which is disposed over the chip positioning plate so as to cover the elastic members and expose the semiconductor chip received in the receiving part; and
a base plate formed of silicon, which supports the semiconductor chip received in the receiving part and is disposed under the chip positioning plate, the base plate having a through hole.

9. A chip tray as claimed in claim 7, wherein the chip tray is used for demarcating a position of the semiconductor chip to be mounted in the wiring substrate at the time of manufacturing the wiring substrate.

10. A chip tray as claimed in claim 7, wherein the through hole of the base plate is used in degassing of gas of the inside of the receiving part and fixing of the semiconductor chip received in the receiving part.

11. A chip tray as claimed in claim 7, wherein the plural receiving parts are disposed in the chip positioning plate of the chip tray.
